(19) United States
(12) Patent Application Publication
(10) Pub. No.: US 2024/0426872 A1
(43) Pub. Date: Dec. 26, 2024

(54) METAL PRODUCT, METHOD OF MANUFACTURING SAME, AND TEST DEVICE HAVING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN, Gyeonggi-do (KR)

(73) Assignee: POINT ENGINEERING CO., LTD., Chungcheongnam-do (KR)

(21) Appl. No.: 18/747,458

(22) Filed: Jun. 19, 2024

(30) Foreign Application Priority Data
Jun. 20, 2023 (KR) 10-2023-0079274

(51) Int. Cl. G01R 1/067

(52) U.S. Cl. CPC G01R 1/06716; G01R 1/06733; G01R 1/06761

(57) ABSTRACT

Proposed are a metal product, a method of manufacturing the same, and a test device having the same. More particularly, proposed are a metal product that has a high degree of freedom of shape and reliability and improves test reliability for a test object, a method of manufacturing the same, and a test device having the same.

### CROSS REFERENCE TO RELATED APPLICATION

The present application claims priority to Korean Patent Application No. 10-2023-0079274, filed Jun. 20, 2023, the entire contents of which is incorporated herein for all purposes by this reference.

### BACKGROUND OF THE INVENTION

### Field of the Invention

The present disclosure relates to a metal product, a method of manufacturing the same, and a test device having the same.

### Description of the Related Art

Metal products can be manufactured using MEMS technology and plating technology, and their application field may vary depending on purposes. As an example, the metal product may be an electrically conductive contact pin for testing a test object. In the following, the background art of the present disclosure will be described by taking an example that the metal product is an electrically conductive contact pin.

A test for electrical characteristics of a semiconductor device is performed by approaching a test object (semiconductor wafer or semiconductor package) to a test device having a plurality of electrically conductive contact pins and then bringing the respective electrically conductive contact pins into contact with corresponding external terminals (solder balls or bumps) on the test object. Examples of test devices include, but are not limited to, probe cards or test sockets.

The testing at the semiconductor wafer level is performed by a probe card.

The probe card is mounted between a wafer and a test equipment head. 8,000 to 100,000 electrically conductive contact pins are provided, and they make contact with pads within individual chips on the wafer to serve as an intermediary to exchange test signals between probe equipment and individual chips. The types of the probe card may be classified into a vertical probe card, a cantilever probe card, and a micro-electro-mechanical system (MEMS) probe card. The conventional electrically conductive contact pin has a structure in which a body of the pin is elastically bent or curved in a convex shape in the horizontal direction by the pressure applied to opposite ends thereof. Due to this structure, a problem arises in that the electrically conductive contact pins arranged at a narrow pitch are brought into contact with and short-circuited to adjacent electrically conductive contact pins when deformed.

The testing at the semiconductor package level is performed by a test socket. Conventional test sockets include a pogo-type socket and a rubber-type socket.

An electrically conductive contact pin (hereinafter referred to as a “pogo-type socket pin”) used in the pogo-type test socket includes a pin portion and a barrel accommodating the pin portion. The pin portion is provided with a spring member between plungers at opposite ends of the pin portion to enable application of required contact pressure and shock absorption at a contact position. In order for the pin portion to slide within the barrel, a gap has to exist between an outer surface of the pin portion and an inner surface of the barrel. However, since the pogo-type socket pin is used by separately manufacturing the barrel and the pin portion and then assembling them together, the gap between the outer surface of the pin portion and the inner surface of the barrel is increased more than necessary, so it is impossible to precisely manage the gap. Therefore, electrical signals are lost and distorted in the process of being transferred to the barrel via the opposite plungers, causing a problem in that contact stability is not constant.

An electrically conductive contact pin (hereinafter referred to as a “rubber-type socket pin”) used in the rubber-type test socket has a structure in which conductive microballs are disposed inside a silicon rubber made of a rubber material. When stress is applied by placing a test object (e.g., a semiconductor package) and closing the socket, conductive microballs made of gold strongly press each other and increase conductivity, making the microballs electrically connected. However, the rubber-type socket pin has a problem in that contact stability is secured only when the socket pin is pressed with an excessive pressing force.

In the case of the rubber-type socket pin, the socket pin is produced by preparing a molding material in which conductive particles are distributed in a fluid elastic material, inserting the molding material into a predetermined mold, and applying a magnetic field in the thickness direction to arrange the conductive particles in the thickness direction. Due to this manufacturing technique, when the distance between magnetic fields is narrowed, the conductive particles are irregularly oriented and a signal flows in the plane direction. Thus, the conventional rubber-type socket pin has limitations in responding to the trend toward narrow pitch technology. In addition, since the pogo-type socket pin is used by separately manufacturing the barrel and the pin portion and then assembling them together, it is difficult to manufacture the socket pin in a small size. Thus, the pogo-type socket pin also has limitations in responding to the trend toward narrow pitch technology.

Accordingly, there is a need to develop a new type of electrically conductive contact pin that can improve the test reliability for a test object to enable compliance with the recent technology trend and a test device having the same.

In manufacturing metal products such as electrically conductive contact pins, they can be manufactured using an MEMS process. A process of manufacturing an electrically conductive contact pin using the MEMS process involves first applying a photoresist to a surface of a conductive substrate and then patterning the photoresist. After that, a metal material is deposited on the exposed surface of the conductive substrate within an opening by electroplating using the photoresist as a mold, and the photoresist and the conductive substrate are removed to obtain an electrically conductive contact pin. The electrically conductive contact pin manufactured using the MEMS process as described above is hereinafter referred to as an MEMS contact pin. The MEMS contact pin has the same shape as the opening formed in the photoresist mold. In this case, the thickness of the MEMS contact pin is affected by the height of the photoresist mold.

When using the photoresist as a mold for electroplating, it is difficult to sufficiently increase the height of the mold only with the use of a single-layer photoresist. As a result, it is also difficult to sufficiently increase the thickness of the MEMS contact pin. The MEMS contact pin needs to be manufactured with a predetermined thickness in consideration of electrical conductivity, restoring force, brittle fracture, etc. In order to increase the thickness of the MEMS contact pin, a mold in which photoresists are stacked in multiple layers may be used. However, in this case, each photoresist layer is slightly stepped, so a problem occurs in that a stepped area minutely remains on side surfaces of the MEMS contact pin. In addition, when the photoresists are stacked in multiple layers, it is difficult to accurately reproduce the shape of the MEMS contact pin having a dimension range of equal to or less than several tens of μm.

The foregoing is intended merely to aid in the understanding of the background of the present disclosure, and is not intended to mean that the present disclosure falls within the purview of the related art that is already known to those skilled in the art.

### DOCUMENTS OF RELATED ART

(Patent document 1) Korean Patent Application Publication No. 10-2018-0004753

### SUMMARY OF THE INVENTION

Accordingly, the present disclosure has been made keeping in mind the above problems occurring in the related art, and one objective of the present disclosure is to provide a metal product having a high degree of freedom of shape and reliability, a method of manufacturing the same, and a test device having the same.

Another objective of the present disclosure is to provide a metal product that improves test reliability for a test object, a method of manufacturing the same, and a test device having the same.

In order to achieve the above objectives, according to one aspect of the present disclosure, there is provided a metal product having an overall length in a length direction, an overall thickness in a thickness direction orthogonal to the length direction, and an overall width in a width direction orthogonal to the length direction. The metal product may be divided into a first body region and a second body region in the thickness direction. A step side surface may be formed due to a dimensional difference in the thickness direction between the first and second body regions, the first body region may be provided on side surfaces thereof excluding the step side surface with a plurality of fine trenches formed in the form of grooves extending along the thickness direction and arranged in parallel along the side surfaces, and the second body region may be provided on side surfaces thereof with a plurality of fine trenches formed in the form of grooves extending along the thickness direction and arranged in parallel along the side surfaces.

In addition, the metal product may include a first surface and a second surface opposite to the first surface. The side surfaces may be surface that connect the first surface and the second surface to each other, and the fine trenches may not be formed on the first surface and the second surface.

In addition, the fine trenches may have a depth in a range of 20 nm to 1 μm.

In addition, a portion of the second body region may form a protrusion that protrudes beyond the first body region. The second body region excluding the protrusion may have a shape that corresponds to a shape of the first body region.

In addition, the first body region may have a thickness greater than a thickness of the second body region.

In addition, the metal product may be an electrically conductive contact pin that is connected to a test object and tests electrical characteristics of the test object.

According to another aspect of the present disclosure, there is provided a test device, including: a metal product; a guide plate into which the metal product is inserted and installed; and a circuit wiring portion configured to be electrically connected to a side of the metal product. The metal products may include: a first body region; and a second body region having a dimension smaller than a dimension of the first body region in a thickness direction dimension. A step side surface may be formed due to a dimensional difference in the thickness direction between the first and second body regions, the first body region may be provided on side surfaces thereof excluding the step side surface with a plurality of fine trenches formed in the form of grooves extending along the thickness direction and arranged in parallel along the side surfaces, and the second body region may be provided on side surfaces thereof with a plurality of fine trenches formed in the form of grooves extending along the thickness direction and arranged in parallel along the side surfaces.

According to another aspect of the present disclosure, there is provided a method of manufacturing a metal product, the method including: forming a first opening by etching a portion of an anodic aluminum oxide film in a thickness direction; forming a lower metal layer by subjecting the first opening to a plating process; forming a patternable material on the lower metal layer; patterning at least a portion of the patternable material to form a second opening; forming a upper metal layer by subjecting the second opening to the plating process; and removing the anodic aluminum oxide film and the patternable material.

In addition, in the forming of the lower metal layer, the lower metal layer may be formed to have a dimension smaller than a dimension of the first opening in the thickness direction.

In addition, in the forming of the upper metal layer, the upper metal layer may be formed to have a dimension greater than a dimension of the lower metal layer in the thickness direction. In addition, after the forming of the upper metal layer, the patternable material may cover an upper surface of the lower metal layer in the thickness direction and a side surface of the upper metal layer in a length direction.

The present disclosure can provide a metal product having a high degree of freedom of shape and reliability, a method of manufacturing the same, and a test device having the same.

The present disclosure can provide a metal product that improves test reliability for a test object, a method of manufacturing the same, and a test device having the same.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a perspective view illustrating a metal product according to a first embodiment;

FIG. 2 is a partially enlarged perspective view of FIG. 1;

FIG. 3 is an enlarged view illustrating fine trenches;

FIG. 4 is a perspective view illustrating a metal product according to a second embodiment;

FIG. 5 is a partially enlarged perspective view of FIG. 4;

FIGS. 6A to 7D are flowcharts illustrating a method of manufacturing a metal product; and

FIG. 8 is a view illustrating a test device having the metal product according to the first embodiment.

### DETAILED DESCRIPTION OF THE INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, thicknesses of films and regions in the figures may be exaggerated. Therefore, variations from the shapes of the illustrations as a result, for example, of manufacturing techniques and/or tolerances, are to be expected. In addition, a limited number of products are illustrated in the drawings by way of example. Thus, the embodiments should not be construed as limited to the particular shapes of regions illustrated herein but are to include deviations in shapes that result, for example, from manufacturing.

A metal product according to a preferred embodiment of the present disclosure refers to an object made of metal with a predetermined thickness, height, and length. The metal product according to the preferred embodiment of the present disclosure may be manufactured using MEMS technology and plating technology, and its application field may vary depending on purposes.

The metal product according to the preferred embodiment of the present disclosure may be an electrically conductive contact pin for testing a test object. The metal product is provided in a test device 1000 and is used to transmit electrical signals by making electrical and physical contact with the test object. The test device 1000 may be a test device 1000 used in a semiconductor manufacturing process, and may be, for example, a probe card or a test socket depending on the test object. However, the test device 1000 according to the preferred embodiment of the present disclosure is not limited thereto and includes any device for checking whether the test object is defective by applying electricity.

Hereinafter, exemplary embodiments of the present disclosure will be described in detail with reference to the drawings.

In the following description, the width direction of metal products MA1 and MA2 refers to the ±x direction indicated in the drawings, the length direction of the metal products MA1 and MA2 refers to the ±y direction indicated in the drawings, and the thickness direction of the metal products MA1 and MA2 refers to the ±z direction indicated in the drawings.

Each of the metal products MA1 and MA2 has an overall length L in the length direction (±y direction), an overall thickness H in the thickness direction (±z direction) orthogonal to the length direction, and an overall width W in the width direction (±x direction) orthogonal to the length direction.

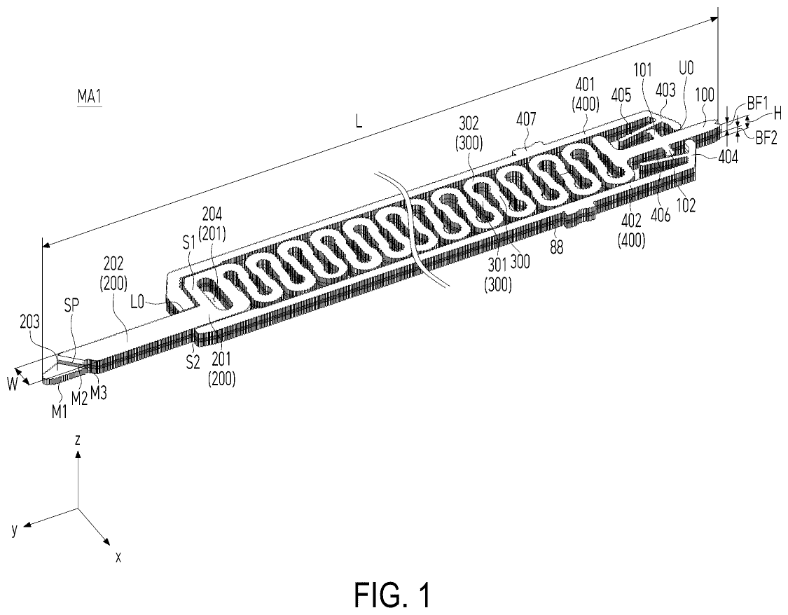

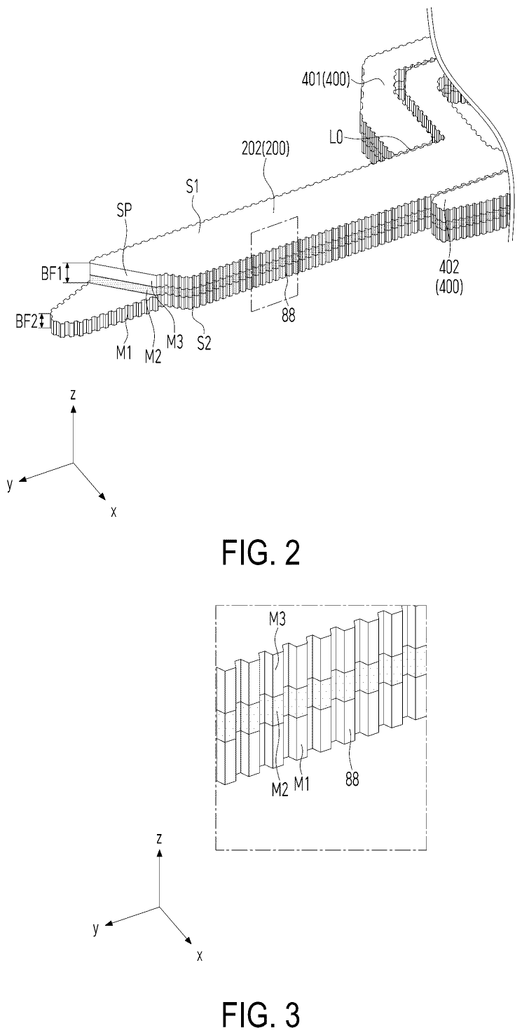

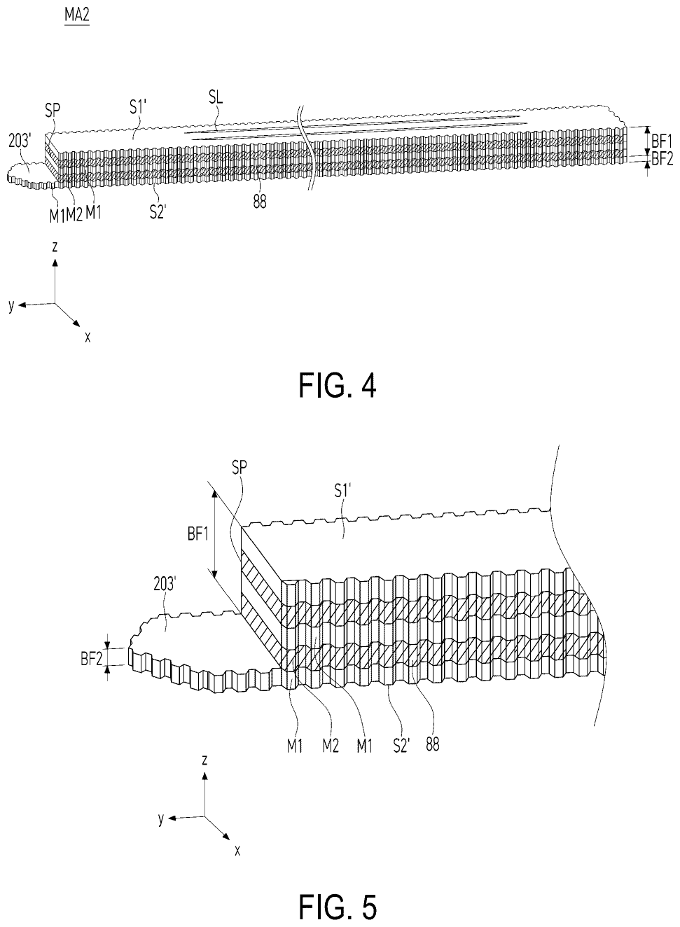

FIG. 1 is a perspective view illustrating a metal product MA1 according to a first embodiment, FIG. 2 is an enlarged perspective view illustrating an end portion in the length direction in FIG. 1, and FIG. 3 is a partially enlarged view illustrating fine trenches 88.

The metal product MA1 according to the first embodiment includes a first surface S1 and a second surface S2 opposite to the first surface S1. The first surface S1 may form an upper surface of the metal product MA1 according to the first embodiment in the thickness direction (±z direction), and the second surface S2 may form a lower surface of the metal product MA1 according to the first embodiment in the thickness direction (±z direction). Side surfaces of the metal product MA1 connect the first surface S1 and the second surface S2 to each other. Therefore, the metal product MA1 according to the first embodiment is composed of the first surface S1, the second surface S2, and the side surfaces.

Referring to FIGS. 1 and 2, the metal product MA1 according to the first embodiment is divided into a first body region BF1 and a second body region BF2 in the thickness direction (±z direction). The first body region BF1 is located at a relatively upper position in the thickness direction (±z direction), and the second body region BF2 is located below the first body region BF1 in the thickness direction (±z direction). The metal product MA1 is formed by sequentially stacking the first body region BF1 and the second body region BF2 in the thickness direction (±z direction) in an integrated and continuous manner.

A plurality of fine trenches 88 are provided on side surfaces of the first body region BF1 and the second body region BF2. Here, the side surfaces of the first body region BF1 refer to surfaces connecting a first surface of the first body region BF1 in the thickness direction (±z direction) and an opposite second surface thereof to each other, and the side surfaces of the second body region BF2 refer to surfaces connecting a first surface of the second body region BF2 in the thickness direction (±z direction) and an opposite second surface thereof to each other.

In a method of manufacturing a metal product, which will be described later, the first body region BF1 and the second body region BF2 are formed by a mold MD made of an anodic aluminum oxide film AL. As a result, the plurality of fine trenches 88 are provided on the side surfaces of the first body region BF1 and the second body region BF2.

Referring to FIGS. 1 to 3, each fine trench 88 is formed in the form of a groove extending along the thickness direction (±z direction) of the metal product MA1 according to the first embodiment, and the plurality of fine trenches 88 are arranged in parallel along the side surfaces of the first and second body regions BF1 and BF2 in a direction orthogonal to the thickness direction (±z direction). Here, the thickness direction (±z direction) of the metal product MA1 refers to a direction in which a metal filling material grows during electroplating.

The fine trenches 88 are formed with a size of equal to or less than 1 μm, which is a size that is distinct from a structure that constitutes the exterior of the metal product MA1. With this, even when determining the position of a protrusion 203 with a vision test device under light irradiation, there is no concern that the fine trenches 88 will be recognized as a structure.

Meanwhile, when determining the position of the protrusion 203 with the vision test device, unlike a step side surface SP, the fine trenches 88 provided on the side surfaces form a diffuse reflection surfaces, so the position of the protrusion 203, which is a structure, can be accurately determined.

The metal product MA1 according to the first embodiment is configured such that the first body region BF1 and the second body region BF2 have different dimensions in the thickness direction (±z direction). The first body region BF1 has a greater dimension in the thickness direction (±z direction) than the second body region BF2, the second body region BF2 has a smaller dimension in the thickness direction (±z direction) than the first body region BF1.

In addition, the metal product MA1 according to the first embodiment is configured such that a portion of the second body region BF2 protrudes beyond the first body region BF1 in the length direction (±y direction). With this, the protrusion 203 is provided, and an upper surface of the protrusion 203 is located at a lower height than an upper surface of the first body region BF1. The shape of the second body region BF2 excluding the protrusion 203 corresponds to that of the first body region BF1. In other words, the first body region BF1 and the second body region BF2 have the same shape except for the protrusion 203. The protrusion 203 is provided at an end of the metal product MA1 according to the first embodiment and may serve as a contact tip that makes contact with a test object 1001 or a circuit wiring portion 1002.

In the method of manufacturing the metal product, which will be described later, the second body region BF2 is first formed using mold MD made of the anodic aluminum oxide film AL, and then a patternable material (specifically, a second patternable material PT2) is provided at an end of the second body region BF2 in the length direction (±y direction). Thereafter, the first body region BF1 is formed on the second body region BF2 so as to have a thickness greater than that of the second body region BF2. As a result, the first body region BF1 is formed with a dimension greater than the second body region BF2 in the thickness direction (±z direction), and the portion of the second body region BF2 is formed to protrude beyond the first body region BF1 in the length direction (±y direction).

As manufactured by the method of manufacturing the metal product, which will be described later, the metal product MA1 according to the first embodiment has no fine trench 88 on a surface thereof covered by the patternable material PT2 provided to form a dimensional difference between the first body region BF1 and the second body region BF2 in the thickness direction (±z direction). Here, the surface covered by the patternable material PT2 includes to the step side surface SP formed by the dimensional difference between the first and second body regions BF1 and BF2 in the thickness direction (±z direction) and at least a portion of an upper surface of the second body region BF2 in the thickness direction (±z direction). The step side surface SP refers to a surface of the first body region BF1 in the length direction (±y direction) exposed in the length direction (±y direction) due to the dimensional difference between the first and second body regions BF1 and BF2 in the thickness direction (±z direction), and the least the portion of the upper surface of the second body region BF2 in the thickness direction (±z direction) refers to the upper surface of the protrusion 203 in the thickness direction (±z direction).

The metal product MA1 according to the first embodiment is configured such that the step side surface SP and the upper surface of the protrusion 203 are provided with no fine trench 88 and the first surface S1 and the second surface S2 are also provided with no fine trench 88. In other words, the fine trenches 88 are provided along the circumference of side surfaces (side surfaces on the x-y plane in FIGS. 1 and 2) of the metal product MA1 according to the first embodiment, and are provided on the side surfaces excluding the step side surface SP.

The fine trenches 88 have a depth and width in the range of 20 nm to 1 μm. Here, because the fine trenches 88 are resulted from the formation of pores formed during the manufacture of the mold MD made of the anodic aluminum oxide film AL, the width and depth of the fine trenches 88 are equal or less than the diameter of the pores of the anodic aluminum oxide film AL. On the other hand, in the process of forming a first opening OP1 as an internal space in the anodic aluminum oxide film AL, portions of the pores of the anodic aluminum oxide film AL may be crushed by an etching solution to at least partially form a fine trench 88 having a depth greater than the diameter of the pores formed during anodization. The anodic aluminum oxide film AL includes numerous pores. The metal product MA1 according to the first embodiment is formed by etching at least a portion of the anodic aluminum oxide film AL to form an internal space and forming a metal filling material inside the internal space through electroplating. Through this process, the fine trenches 88 are formed on the side surfaces of the metal product MA1 according to the first embodiment due to contact between the metal product MA1 and the pores of the anodic aluminum oxide film AL. The metal product MA1 is provided with no fine trenches 88 in areas that do not make contact with the mold MD made of the anodic aluminum oxide film AL during the manufacturing process. In other words, since the metal product MA1 according to the first embodiment is manufactured using the mold MD made of the anodic aluminum oxide film AL, the fine trenches 88 are provided in areas (the side surfaces of the first body region BF1 and the side surfaces of the second body region BF2 excluding the step side surface SP) that are in contact with the mold MD made of the anodic aluminum oxide film AL, the fine trenches 88 are not provided in areas (the first and second surfaces S1 and S2 and the step side surface SP) that are not in contact with the mold MD made of the anodic aluminum oxide film AL.

The fine trenches 88 can contribute to increasing the surface area of the side surfaces of the metal product MA1 according to the first embodiment. Due to the fine trenches 88 on the side surfaces thereof excluding the step side surface SP, the metal product MA1 according to the first embodiment can quickly dissipate heat generated in the metal product MA1. As a result, a temperature rise of the metal product MA1 can be suppressed.

The metal product MA1 according to the first embodiment is formed by stacking a plurality of metal layers in the thickness direction (±z direction) of the metal product MA1. The plurality of metal layers include a first metal layer M1, a second metal layer M2, and a third metal layer M3.

The first metal layer M1 is a metal having relatively high wear resistance compared to the second metal layer M2, and may be made of a metal selected from the group consisting of rhodium (Rh), platinum (Pt), iridium (Ir), palladium (Pd), nickel (Ni), manganese (Mn), tungsten (W), phosphorus (Ph), and an alloy of these metals; the group consisting of a palladium-cobalt (PdCo) alloy and a palladium-nickel (PdNi) alloy; or the group consisting of a nickel-phosphorus (NiPh) alloy, a nickel-manganese (NiMn), a nickel-cobalt (NiCo) alloy, and a nickel-tungsten (NiW) alloy. The plurality of metal layers may be made of the same type of metal or different types of metal.

The second metal layer M2 is a metal having relatively high electrical conductivity compared to the first metal layer M1, and may be made of a metal selected from the group consisting of copper (Cu), silver (Ag), gold (Au), and an alloy of these metals. However, the present disclosure is not limited thereto.

The first body region BF1 may be formed by the first metal layer M1 and the second metal layer M2. The first metal layer M1 is provided in the thickness direction (±z direction) of the metal product MA1 according to the first embodiment, and the second metal layer M2 is provided between first metal layers M1. As an example, the metal product MA1 according to the first embodiment is provided by alternately stacking the first metal layer M1, the second metal layer M2, and the first metal layer M1 in the thickness direction (±z direction). The number of stacked metal layers constituting the first body region BF1 may be at least three.

The second body region BF2 may be formed by the third metal layer M3. The third metal layer M3 may be made of the same metal as or a different metal from the first metal layer M1 or the second metal layer M2 constituting the first body region BF1. In the metal product MA1 according to the first embodiment, the protrusion 203 is formed in the second body region BF2. Therefore, the second body region BF2 is preferably made of a metal with high wear resistance and may be made of a metal selected from the materials used for the first metal layer M1.

The metal product MA1 according to the first embodiment may be an electrically conductive contact pin that is connected to the test object 1001 and tests the electrical characteristics of the test object 1001. To this end, the metal product MA1 according to the first embodiment includes a first connection portion 100, a second connection portion 200, and an elastic portion 300 provided with the first connection portion 100 and/or the second connection portion 200 and being elastically deformable in the length direction (±y direction). A first contact point of the first connection portion 100 is connected to the circuit wiring portion 1002, and the second connection portion 200 is connected to the test object 1001. The elastic portion 300 enables the first connection portion 100 and the second connection portion 200 to be elastically displaced in the length direction (±y direction) of the metal product MA1 according to the first embodiment. The first connection portion 100 is elastically displaced relative to the second connection portion 200 in the length direction (±y direction) by the elastic portion 300.

The first connection portion 100, the second connection portion 200, and the elastic portion 300 are integrally provided with each other. The first connection portion 100, the second connection portion 200, and the elastic portion 300 are manufactured simultaneously through a plating process. A conventional pogo-type electrically conductive contact pin is provided by separately manufacturing a barrel and a pin portion and then assembling them. However, the metal product

MA1 according to the first embodiment is provided as a single body by simultaneously manufacturing the first connection portion 100, the second connection portion 200, and the elastic portion 300 through the plating process. In addition, while the conventional pogo-type electrically conductive contact pin has a spiral spring, the elastic portion 300 of the metal product MA1 according to the first embodiment is formed in the form of a leaf spring.

The elastic portion 300 is formed by alternately connecting a plurality of straight portions 301 and a plurality of curved portions 302. Each of the straight portions 301 connects the curved portions 302 adjacent horizontally in the width direction (±x direction), and each of the curved portions 302 connects the straight portions 301 adjacent vertically in the length direction (±y direction). The curved portions 302 have an arc shape.

The straight portions 301 are disposed at a central portion of the elastic portion 300 in the width direction (±x direction), and the curved portions 302 are disposed at outer peripheral portions of the elastic portion 300 in the width direction (±x direction). The straight portions 301 are provided parallel to the width direction (±x direction) so that the curved portions 302 are more easily deformed by contact pressure.

The elastic portion 300 is integrally connected to the first connection portion 100 through a straight portion 301 provided at an upper portion thereof in the length direction (±y direction), and is integrally connected to the second connection portion 200 through a curved portion 302 provided at a lower portion thereof in the length direction (±y direction).

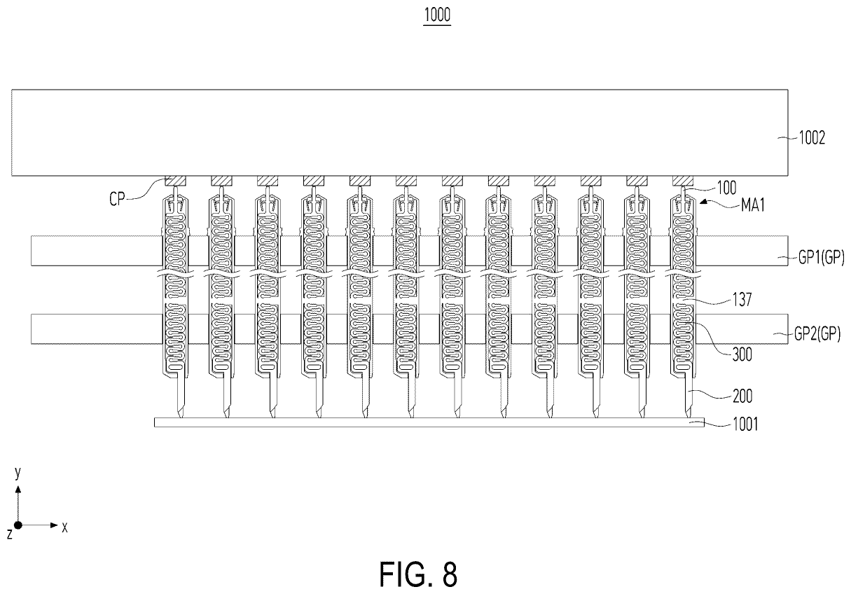

The elastic portion 300 includes an intermediate fixing portion 137 provided at a portion thereof in the length direction (±y direction) and integrally connecting an outer wall portion 400 and the elastic portion 300 to each other. The intermediate fixing portion 137 is omitted in FIG. 1 and is illustrated in FIG. 8.

The elastic portion 300 has a uniform cross-sectional shape in the thickness direction (±z direction) of the metal product MA1 according to the first embodiment. In addition, the elastic portion 300 has a uniform thickness throughout. The elastic portion 300 is formed by repeatedly bending a plate having an actual width t in an “S” shape, and the actual width t of the plate is uniform throughout. The ratio of the actual width t of the plate to the thickness of the plate is in the range of 1:5 to 1:30.

The first connection portion 100 has a first end serving as a free end and a second end connected to the upper portion of the elastic portion 300 in the length direction (±y direction) so that the first connection portion 100 is elastically movable vertically by contact pressure. The second connection portion 200 has a first end serving as a free end and a second end connected to the lower portion of the elastic portion 300 in the length direction (±y direction) so that the second connection portion 200 is elastically movable vertically by contact pressure.

The metal product MA1 according to the first embodiment includes the outer wall portion 400 outside the elastic portion 300 in the width direction (±x direction). The outer wall portion 400 is provided outside the elastic portion 300 in the width direction (±x direction) along the length direction (±y direction) of the metal product MA1 according to the first embodiment. The outer wall portion 400 is composed of a pair of a first outer wall portion 401 and a second outer wall portion 402 facing each other in the width direction (±x direction) with the elastic portion 300 interposed therebetween. The outer wall portion 400 functions to guide the elastic portion 300 to be compressed and extended in the length direction of the metal product MA1 according to the first embodiment and prevent the elastic portion 300 from buckling by bending or curving in the horizontal direction as it is compressed.

The first outer wall portion 401 and the second outer wall portion 402 are configured such that first ends thereof in the length direction (±y direction) are brought close to each other but are spaced apart from each other to form an upper opening UO and second ends thereof in the length direction (±y direction) are brought close to each other but are spaced apart from each other to form a lower opening LO. The upper opening UO and the lower opening LO function to respectively prevent the first and second connection portions 100 and 200 from excessively protruding from the outer wall portion 400 by a restoring force of the elastic portion 300.

The metal product MA1 according to the first embodiment includes a locking portion 407 protruding from the outer wall portion 400 in the width direction (±x direction). The locking portion 407 may be provided at an upper portion of the metal product MA1 in the length direction (±y direction). The locking portion 407 functions to enable the metal product MA1 to be caught and fixed to a guide plate GP. The locking portion 407 may be provided to be caught on at least one guide plate GP. Preferably, the locking portion 407 is provided to be caught on an upper guide plate GP1 located toward the circuit wiring portion 1002. In this case, the locking portion 407 may be provided at the upper portion of the metal product MA1 in the length direction (±y direction) at a position opposite to the protrusion 203 in the length direction (±y direction). A pair of locking portions 407 are provided facing each other in the width direction (±x direction). Each of the locking portions 407 is provided on the outer wall portion 400 provided at each side of the elastic portion 300 in the width direction (±x direction). The form in which the metal product MA1 according to the first embodiment is provided with the locking portion 407 is not limited thereto, and includes all forms capable of forming a structure in which the metal product MA1 is caught and fixed to the guide plate GP.

The first outer wall portion 401 includes a first door portion 403 extending toward the upper opening UO, and the second outer wall portion 402 includes a second door portion 404 extending toward the upper opening UO. The first door portion 403 and the second door portion 404 face each other and are spaced apart from each other by a gap that defines the upper opening UO. The dimension of the upper opening UO in the width direction (±x direction) is formed to be smaller than that of the straight portions 301 of the elastic portion 300 in the width direction (±x direction).

The first outer wall portion 401 includes a first extension portion 405 extending in the length direction (±y direction) in an inner space, and the second outer wall portion 402 includes a second extension portion 406 extending in the length direction (±y direction) in the inner space.

More specifically, the first extension portion 405 is connected to the first door portion 403. The first extension portion 405 has a first end connected to the first door portion 403, and a second end extending in the length direction (±y direction) in the inner space formed between the first and second outer wall portions 401 and 402 facing each other in the width direction (±x direction) and serving as a free end. The second extension portion 406 is connected to the second door portion 404. The second extension portion 406 has a first end connected to the second door portion 404, and a second end extending in the length direction (±y direction) in the inner space formed between the first and second outer wall portions 401 and 402 and serving as a free end.

The first connection portion 100 is vertically moved downward in the length direction (±y direction) inside the outer wall portion 400. Therefore, additional contact points are formed between the first connection portion 100 and the outer wall portion 400. The second connection portion 200 is vertically moved upward in the length direction (±y direction) inside the outer wall portion 400, and a second contact point thereof performs a wiping operation. During a process in which the metal product MA1 according to the first embodiment test the test object 1001, the metal product MA1 maintains a vertical state, and the second connection portion 200 performs the wiping operation on the test object 1001 as it is tilted while maintaining contact pressure with the test object 1001.

The first connection portion 100 is connected to the straight portion 301 of the elastic portion 300 and has a rod shape extending in the length direction of the metal product MA1 according to the first embodiment. The first connection portion 100 vertically passes through the upper opening UO at the first ends of the first and second outer wall portions 401 and 402 in the length direction (±y direction).

Meanwhile, since the dimension of the straight portions 301 of the elastic portion 300 in the width direction (±x direction) is formed to be greater than that of the upper opening UO in the width direction (±x direction), the straight portions 301 do not pass through the upper opening UO. With this, an upward stroke of the first connection portion 100 is limited.

When the first connection portion 100 is vertically moved downward inside the outer wall portion 400, the first connection portion 100 is brought into contact with the outer wall portion 400 as the width of the upper opening UO is reduced, thereby forming additional contact points.

The first connection portion 100 includes a first protruding piece 101 extending toward the first extension portion 405 in the width direction (±x direction) and a second protruding piece 102 extending toward the second extension portion 406. When the first connection portion 100 is moved downward by a pressing force, the first protruding piece 101 and the second protruding piece 102 are brought into contact with the first extension portion 405 and the second extension portion 406, respectively. With this, additional contact points are formed.

The first and second extension portions 405 and 406 are formed to be inclined closer to the first connection portion 100 from the first ends toward the second ends thereof in the length direction (±y direction). With this, when the first connection portion 100 is vertically moved downward, the first protruding piece 101 and the second protruding piece 102 press the first extending portion 405 and the second extending portion 406, respectively. As a result, the gap between the first door portion 403 and the second door portion 404 is reduced.

In other words, as the first connection portion 100 is vertically moved downward, the first door portion 403 and the second door portion 404 are deformed to approach each other, thereby reducing the width of the upper opening UO. As such, the vertical downward movement of the first connection portion 100 inside the outer wall portion 400 causes the first connection portion 100 to be brought into contact with the outer wall portion 400 as the width of the upper opening UO is reduced, thereby forming additional contact points.

As the first connection portion 100 is moved downward, the first and second protruding pieces 101 and 102 and the first and second extension portions 405 and 406 are primarily brought into contact with each other to form additional contact points, and as the first connection portion 100 is further moved downward, the first and second door portions 403 and 404 and the first connection portion 100 are secondarily brought into contact with each other to form additional contact points. Due to the vertical downward movement of the first connection portion 100, an additional current path is formed between the first connection portion 100 and the outer wall portion 400. This additional current path is formed directly from the outer wall portion 400 to the first connection portion 100 without passing through the elastic portion 300. This enables the metal product MA1 according to the first embodiment to have a more stable electrical connection.

The width of the upper opening UO is reduced in proportion to a downward movement distance of the first connection portion 100. In addition, when downward pressure is applied to the first connection portion 100 even after the contact of the first and second door portions 403 and 404 with the first connection portion 100, a frictional force between the first and second door portions 403 and 404 and the first connection portion 100 is further increased. The increased frictional force prevents excessive downward movement of the first connection portion 100. With this, it is possible to prevent excessive compression deformation of the elastic portion 300 (specifically, the upper portion of the elastic portion 300 connected to the first connection portion 100).

The second connection portion 200 is connected to the lower portion of the elastic portion 300 at an upper portion thereof in the direction (±y direction), with an end passing through the lower opening LO.

The second connection portion 200 includes an inner body 201 connected to the elastic portion 300, an extension body 202 protruding to the outside of the outer wall portion 400 in the length direction (±y direction), and the protrusion 203 provided at an end of the extension body 202.

The second connection portion 200 repeatedly performs lifting and lowering operations. Here, the dimension of a lower surface of the inner body 201 in the width direction (±x direction) is formed to be greater than that of the lower opening LO the width direction (±x direction) so that the inner body 201 is prevented from deviating to the outside of the outer wall portion 400.

A hollow portion 204 is formed in the inner body 201. The hollow portion 204 is formed to pass through the inner body 201 in the thickness direction (±z direction). With the configuration of the hollow portion 204, the inner body 201 is compressable and deformable by pressing force, and this compression and deformation of the inner body 201 enables the wiping operation of the protrusion 203 to be performed more smoothly.

The extension body 202 extends from an upper surface of the inner body 201 so that at least a portion of the extension body 202 passes through the lower opening LO to be located outside the outer wall portion 400.

The protrusion 203 is provided at the end of the extension body 202. The protrusion 203 is formed to have a thickness smaller than that of the extension body 202. The second connection portion 200 is configured such that the protrusion 203 is formed by the portion of the second body region BF2 protruding beyond the first body region BF1 in the length direction (±y direction). The protrusion 203 corresponds to the second body region BF2.

During the wiping operation of the protrusion 203, shavings are generated from an oxide layer formed on a surface of the test object 1001. The shavings tend to grow continuously as they are deposited and clumped together. However, these shavings are caught at the end of the extension body 202 serving as a root portion of the protrusion 203 and are unable to grow any further and are naturally guided to fall. As such, with the configuration of the protrusion 203 formed at the end of the extension body 202 with a smaller thickness than the extension body 202, the continuous growth of oxide layer shavings generated during the wiping operation can be prevented.

According to the method of manufacturing the metal product, which will be described later, it is possible to make the actual width t of the plate constituting the elastic portion 300 equal to or less than 10 μm, more preferably 5 μm. As it is possible to form the elastic portion 300 by bending the plate having an actual width t of 5 μm, it is possible to reduce the overall width W of the metal product MA1. As a result, it is possible to cope with a narrower pitch. In addition, the overall thickness H may be configured in the range of 100 μm to 300 μm. With this, it is possible to shorten the length of the elastic portion 130 while preventing damage to the elastic portion 130. Also, it is possible for the elastic portion 130 to have an appropriate contact pressure by the configuration of the plate even when the length thereof is shortened. According to the method of manufacturing the metal product, as it is possible to increase the overall thickness H compared to the actual width t of the plate constituting the elastic portion 300, the resistance to moments acting in the front and rear directions of the elastic portion 300 is increased, resulting in improved contact stability of the metal product MA1 according to the first embodiment.

As it is possible to shorten the length of the elastic portion 300, the overall thickness H and the overall length L of the metal product MA1 according to the first embodiment have a ratio in the range of 1:3 to 1:9. Preferably, the overall length L of the metal product MA1 according to the first embodiment is in the range of 300 μm to 3 mm, and more preferably 450 μm to 600 μm. According to the method of manufacturing the metal product, which will be described later, as it is possible to shorten the overall length L of the metal product MA1 according to the first embodiment, it is possible for the metal product MA1 to easily respond to high-frequency characteristics. In addition, the elastic recovery time of the elastic portion 300 can be shortened, thereby shortening the test time.

The overall thickness H and the overall width W of the metal product MA1 according to the present disclosure have a ratio in the range of 1:1 to 1:5. Preferably, the overall length L of the metal product MA1 according to the first embodiment is in the range of 100 μm to 300 μm, and the overall width W of the metal product MA1 according to the first embodiment is in the range of 100 μm to 300 μm. By shortening the overall width W of the metal product MA1 according to the first embodiment as described above, it is possible to implement a narrower pitch.

Meanwhile, the overall thickness H and the overall width W of the metal product MA1 according to the first embodiment may be configured to be substantially the same. Thus, it is not necessary to join a plurality of separately manufactured metal products MA1 according to the first embodiment in the thickness direction so that the overall thickness H and the overall width W become substantially the same.

In addition, as it is possible to make the overall thickness H and the overall width W of the metal product MA1 according to the first embodiment substantially the same, the resistance to moments acting in the front and rear directions of the metal product MA1 according to the first embodiment is increased, resulting in improved contact stability. Furthermore, with the configuration in which the overall thickness H of the metal product MA1 according to the first embodiment is equal to or greater than 100 μm and the ratio of the overall thickness H to the overall width W thereof is in the range of 1:1 to 1:5, overall durability and deformation stability of the metal product MA1 according to the first embodiment can be improved and thereby contact stability with an external terminal CP can be improved. In addition, as the overall thickness H of the metal product MA1 according to the first embodiment is configured to be equal to or greater than 100 μm, it is possible to improve current carrying capacity.

When a metal product is manufactured using a photoresist as a mold MD, the overall thickness H thereof is inevitably smaller than the overall width W thereof. For example, the overall thickness H of the metal product may be less than 40 μm and the overall thickness H and the overall width W thereof may have a ratio in the range of 1:2 to 1:10. Thus, the resistance to moments that deform the metal product in the front and rear directions by contact pressure is weak. In order to prevent problems occurring due to excessive deformation of the elastic portion on front and rear surfaces of the metal product, it should be considered to additionally form a housing on the front and rear surfaces of the metal product. However, the metal product MA1 according to the first embodiment manufactured by the method of manufacturing the metal product, which will be described later, does not require an additional housing.

Next, a second embodiment according to the present disclosure will be described. However, the embodiment described below will be mainly described in terms of characteristic elements in comparison with the first embodiment, and descriptions of the same or similar elements to the first embodiment will be omitted. In the following, the same elements as those of the first embodiment are given the same reference numerals.

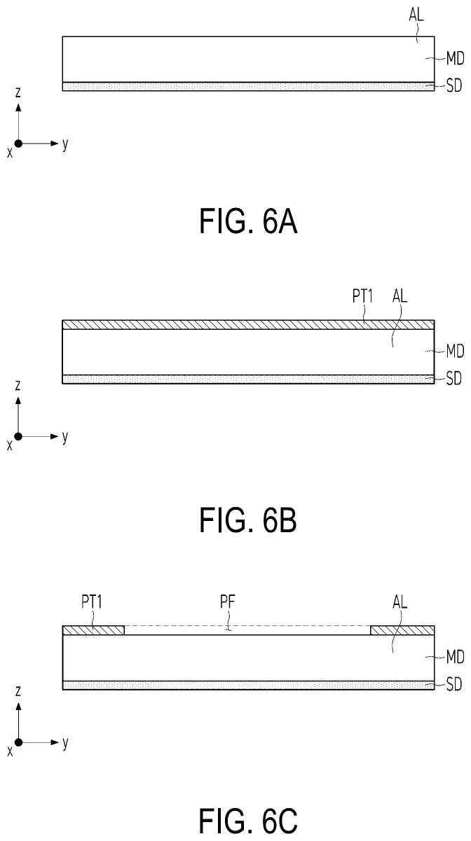

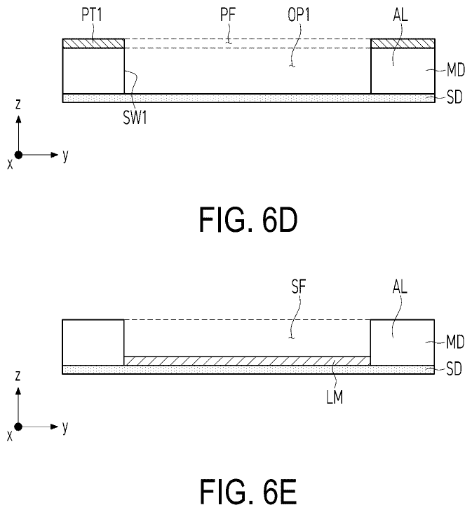

FIG. 4 is a perspective view illustrating a metal product MA2 according to the second embodiment, and FIG. 5 is a partially enlarged perspective view of FIG. 4.

The metal product MA2 according to the second embodiment is divided into a first body region BF1′ and a second body region BF2′ having a dimensional difference in the thickness direction (±z direction), and a plurality of fine trenches 88 are provided on side surfaces of the first body region BF1′ and the second body region BF2′. The first body region BF1′ has a greater dimension in the thickness direction (±z direction) than the second body region BF2′, and the second body region BF2′ has a smaller dimension in the thickness direction (±z direction) than the first body region BF1′. At least a portion of the second body region BF2′ protrudes from the first body region BF1′in the length direction (±y direction) to form a protrusion 203′.

Due to the dimensional difference in the thickness direction (±z direction) between the first body region BF1′ and the second body region BF2′, the metal product MA2 according to the second embodiment has a step side surface SP defined by a side surface of the first body region BF1′ exposed to the outside in the length direction (±y direction).

The metal product MA2 according to the second embodiment is provided with the fine trenches 88 on the side surfaces thereof excluding the step side surface SP. The fine trenches 88 are provided along the circumference of the side surfaces of the metal product MA2 according to the second embodiment, and are provided on the side surfaces excluding the step side surface SP.

Therefore, the metal product MA2 according to the second embodiment is provided with the fine trenches 88 only on the side surfaces thereof excluding a first surface S1′, a second surface S2′, and the step side surface SP.

Referring to FIGS. 4 and 5, the metal product MA2 according to the second embodiment is formed to extend in the length direction (±y direction).

The first body region BF1′ may be formed to have a quadrangular cross-section. The second body region BF2′ may be formed such that the cross-section thereof excluding the protrusion 203′ has a quadrangular shape corresponding to the cross-sectional shape of the first body region BF1′. In this case, guide holes of an upper guide plate GP1 and a lower guide plate GP2 may have a quadrangular cross-section corresponding to the quadrangular cross-sectional shape of the metal product MA2 according to the second embodiment excluding the protrusion 203′. With the configuration of the guide holes with a quadrangular cross-section, the metal product MA2 can be prevented from rotating within the guide holes so that the metal product MA2 is elastically deformed in a uniform direction, thereby preventing interference between metal products MA2 and implementing a narrower pitch.

The metal product MA2 according to the second embodiment includes a slit SL passing through the second body region BF2′ excluding the protrusion 203′ and the first body region BF1′ in the thickness direction (±z direction). The slit SL passes through the first surface S1′ and the second surface S2′ of the metal product MA2 in the thickness direction (±z direction). The slit SL is provided in a portion of the metal product MA2 according to the second embodiment excluding the protrusion 203′ and is formed in the form of an empty space inside the metal product MA2 according to the second embodiment.

The slit SL is formed to extend along the length direction (±y direction) of the metal product MA2 according to the second embodiment. At least one slit SL may be provided. In the drawings, two slits SL are illustrated. By including the slit SL, the metal product MA2 according to the second embodiment is shortened in the overall length thereof while securing the desired overdrive amount and the desired needle pressure or the allowable time-current characteristics. Due to the shortened overall length, the inductance of the metal product MA2 according to the second embodiment is reduced. As a result, the high-frequency characteristics of the metal product MA2 according to the second embodiment can be improved.

The slit SL may be formed such that the internal width thereof gradually decreases from a center to an end thereof. With this, a beam portion provided at each side of the slit SL in the width direction (±x direction) has a root portion whose width increases from a center to an end thereof, so there is an effect of relieving stress concentration occurring at both ends of the slit SL in the length direction (±y direction).

The metal product MA2 according to the second embodiment is provided by stacking a plurality of metal layers in the thickness direction (±z direction). The plurality of metal layers are metal layers made of different materials. The plurality of metal layers include a first metal layer M1 and a second metal layer M2. The first metal layer M1 is a metal having relatively high wear resistance compared to the second metal layer M2, and may be made of a metal selected from the group consisting of rhodium (Rh), platinum (Pt), iridium (Ir), palladium (Pd), nickel (Ni), manganese (Mn), tungsten (W), phosphorus (Ph), and an alloy of these metals; the group consisting of a palladium-cobalt (PdCo) alloy and a palladium-nickel (PdNi) alloy; or the group consisting of a nickel-phosphorus (NiPh) alloy, a nickel-manganese (NiMn), a nickel-cobalt (NiCo) alloy, and a nickel-tungsten (NiW) alloy. The second metal layer 102 is a metal having relatively high electrical conductivity compared to the first metal layer 101, and may be made of a metal selected from the group consisting of copper (Cu), silver (Ag), gold (Au), and an alloy of these metals.

The first metal layer M1 is provided in the second body region BF2′ and forms a lower surface of the metal product MA2 according to the second embodiment. The second metal layer M2 is provided at the lowest layer of the first body region BF1′ in the thickness direction (±z direction) and is stacked on the first metal layer M1 constituting the second body region BF2′. As an example, the first body region BF1′ may be provided by alternately stacking the first and second metal layers M1 in the order of the second metal layer M2, the first metal layer M1, the second metal layer M2, and the number of stacked layers may be at least three. In the drawings, four metal layers are illustrated to be stacked to form the first body region BF1′.

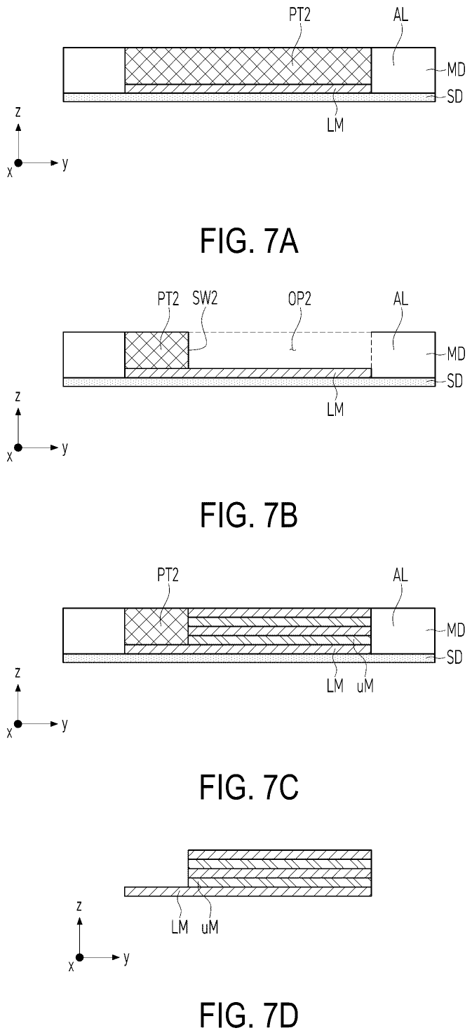

Hereinafter, a method of manufacturing metal products MA1 and MA2 will be described. The metal products MA1 and MA2 include the metal products MA1 and MA2 according to the first and second embodiments. Therefore, the metal products MA1 and MA2 according to the first and second embodiments described above are manufactured by the method of manufacturing the metal products MA1 and MA2. FIGS. 6A to 7D sequentially illustrate the method of manufacturing the metal products MA1 and MA2.

First, as illustrated in FIG. 6A, a mold MD is prepared. The mold MD is made of an anodic aluminum oxide film AL. The anodic aluminum oxide film AL means a film formed by anodizing a metal as a base material, and pores mean holes formed in the process of forming the anodic aluminum oxide film AL by anodizing the metal. For example, when the metal as the base material is aluminum (Al) or an aluminum alloy, the anodization of the base material forms the anodic aluminum oxide film AL consisting of anodized aluminum (Al₂O₃) on a surface of the base material. However, the metal as the base material is not limited thereto, and includes Ta, Nb, Ti, Zr, Hf, Zn, W, Sb, or an alloy of these metals. The resulting anodic aluminum oxide film AL includes a barrier layer in which no pores are formed therein vertically, and a porous layer in which pores are formed therein. After removing the base material on which the anodic aluminum oxide film AL having the barrier layer and the porous layer is formed, only the anodic aluminum oxide film AL consisting of anodized aluminum (Al₂O₃) remains. The anodic aluminum oxide film AL may have a structure in which the barrier layer formed during the anodization is removed to expose the top and bottom of the pores, or a structure in which the barrier layer formed during the anodization remains to close one of the top and bottom of the pores.

The anodic aluminum oxide film AL has a coefficient of thermal expansion of 2 to 3 ppm/° C. With this range, the anodic aluminum oxide film AL only undergoes a small amount of thermal deformation due to temperature when exposed to a high-temperature environment. Thus, even when the metal products MA1 and MA2 are manufactured in a high-temperature environment, precise metal products MA1 and MA2 can be manufactured without thermal deformation.

Conventionally, a mold MD for manufacturing metal products MA1 and MA2 was manufactured using a photoresist instead of the anodic aluminum oxide film AL. The mold MD is manufactured by repeating the process of spraying and hardening the photoresist in a liquid form, forming layers in units of 30 μm. Even after completing the metal products MA1 and MA2, they are prone to deformation due to joints formed between the layers like bamboo. The conventional mold MD made of the photoresist had limitations in stacking the mold MDs high, and precise patterning was also difficult.

However, this problem can be solved by using the mold MD made of the anodic aluminum oxide film AL. First, precise patterning is possible because the anodic aluminum oxide film AL, which is already in a solid state, is etched. In addition, unlike the conventional method, the completed metal products MA1 and MA2 do not have layer joints and do not deform after use. The metal products MA1 and MA2 also have higher electrical conductivity than conventional pins and can be used without signal loss even in a high-frequency band of 100 GHz (gigahertz) or more.

According to the method of manufacturing the metal products MA1 and MA2, since the metal products MA1 and MA2 are manufactured using the mold MD made of the anodic aluminum oxide film AL instead of the mold MD made of the photoresist, there is an effect of realizing shape precision and a fine shape, which were limited in realization with the mold MD made of the photoresist. In addition, when the conventional mold MD made of the photoresist is used, metal products MA1 and MA2 with a thickness of 40 μm can be manufactured, but when the mold MD made of the anodic aluminum oxide film AL is used, metal products MA1 and MA2 with a thickness in the range of 100 μm to 300 μm can be manufactured. With this, multilayer plating using first and second metal layers 101 and 102 is possible, thereby improving elastic strength and electrical conductivity at the same time.

A seed layer SD is provided under the mold MD. The seed layer SD may be provided on a lower surface of the mold MD before a first opening OP1 is formed in the mold MD. The seed layer SD may be made of a different metal material from that of the first and second metal layers M1 and M2. For example, the seed layer SD may be made of copper (Cu), and may be formed by a deposition method.

Then, referring to FIG. 6B, a first patternable material PT1 is provided on an upper surface of the mold MD. The first patternable material PT1 may be a photosensitive material that can be subjected to exposure and development processes. The first patternable material PT1 may be a photosensitive resin, and preferably includes a photoresist.

Then, referring to FIG. 6C, a patterning region PF is formed by patterning at least a portion of the first patternable material PT1. The first patternable material PT1 is patterned through exposure and development processes. As a result, the patterning region PF is formed on the upper surface of the mold MD.

Then, referring to FIG. 6D, the anodic aluminum oxide film AL of the mold MD exposed by the patterning region PF is etched in the thickness direction (±z direction) to form the first opening OP1. The anodic aluminum oxide film AL is etched by an etching solution, resulting in forming the first opening OP1 having a dimension in the length direction (±y direction) equal to that of the patterning region PF in the length direction (±y direction) in the mold MD. Since the first opening OP1 is resulted from etching the anodic aluminum oxide film AL, a plurality of fine trenches 88 are formed on side walls SW1 of the first opening OP1. The seed layer SD provided on the lower surface of the mold MD is exposed inside the first opening OP1. Here, the side walls SWI of the first opening OP1 refer to portions located on side surfaces connecting upper and lower surfaces of the anodic aluminum oxide film AL in the thickness direction (±z direction).

Then, referring to FIG. 6E, a metal plating process is performed using the seed layer SD exposed inside the first opening OP1 to form a lower metal layer LM. The lower metal layer LM is formed to have a dimension smaller than that of the first opening OP1 in the thickness direction (±z direction). With this, inside the first opening OP1 in which only the lower metal layer LM is formed, a spare region SF is formed due to a difference in the dimension of the lower metal layer LM in the thickness direction (±z direction) and the dimension of the first opening OP1 A in the thickness direction (±z direction). Therefore, the dimension of the spare region SF in the thickness direction (±z direction) is greater than that of the lower metal layer LM in the thickness direction (±z direction).

The lower metal layer LM corresponds to the second body region BF2 described above. Therefore, the lower metal layer LM is made of the same material as that of the first metal layer M1 constituting the second body region BF2.

Then, referring to FIG. 7A, a second patternable material PT2 is formed on an upper surface of the lower metal layer LM. The second patternable material PT2 has a thickness equal to the dimension of the spare region SF in the thickness direction (±z direction) and is entirely applied to the spare region SF. The second patternable material PT2 may be applied using the same method as that for the first patternable material PT1. The second patternable material PT2 may be made of the same material as that of the first patternable material PT1.

The second patternable material PT2 is provided to form a dimensional difference in the length direction (±y direction) and a dimensional difference in the thickness direction (±z direction) between the lower metal layer LM and the upper metal layer UM stacked on the lower metal layer LM.

Then, referring to FIG. 7B, a second opening OP2 is formed by patterning at least a portion of the second patternable material PT2.

Specifically, the least the portion of the second patternable material PT2 corresponding to a second end of the lower metal layer LM in the length direction (±y direction) is patterned so that the second patternable material PT2 is provided only on a first end of the lower metal layer LM in the length direction (±y direction). The second opening OP2 is formed by a region where the at least the portion of the second patternable material PT2 is patterned.

The dimension of the at least the patterned portion of the second patternable material PT2 in the length direction (±y direction) is greater than that of at least an unpatterned portion of the second patternable material PT2 in the length direction (±y direction). Therefore, the dimension of the second opening OP2 in the length direction (±y direction) is greater than that of the unpatterned portion of the second patternable material PT2 in the length direction (±y direction).

The dimension of the second opening OP2 in the thickness direction (±z direction) is equal to that of the spare region SF in the thickness direction (±z direction), the dimension of the spare region being greater than that of the lower metal layer LM in the thickness direction (±z direction). Therefore, the dimension of the second opening OP2 in the thickness direction (±z direction) is greater than that of the lower metal layer LM in the thickness direction (±z direction).

The second opening OP2 is formed by patterning the second patternable material PT2 provided at a position corresponding to the second end of the lower metal layer LM in the length direction (±y direction), except for the second patternable material PT2 provided at a position corresponding to the first end of the lower metal layer LM in the length direction (±y direction). Therefore, one surface of side walls SW2 of the second opening OP2 is composed of the second patternable material PT2, and the remaining surfaces are composed of the anodic aluminum oxide film AL of the mold MD. Here, the side walls SW2 of the second opening OP2 refer to portions located on the same plane (on the x-y plane in the drawings) as side surfaces connecting upper and lower surfaces of the second patternable material PT2 applied to the spare region SF in the thickness direction (±z direction).

The second patternable material PT2 is provided in the spare region SF of the first opening OP1, and the second opening OP2 is provided by patterning the at least the portion of the second patternable material PT2. Therefore, except for one surface of the side walls SW2 of the second opening OP2 composed of the second patternable material PT2, the remaining surfaces are composed of the anodic aluminum oxide film AL constituting the side walls SW1 of the first opening OP1.

As an example, the side walls SW2 of the second opening OP2 may have four surfaces. Specifically, the four surfaces may be composed of a first surface and a second surface in the width direction (±x direction) and a first surface and a second surface in the length direction (±y direction). Among the four surfaces, one surface (specifically, the first surface in the length direction (±y direction)) is composed of the second patternable material PT2 due to the unpatterned portion of the second patternable material PT2, and the remaining three surfaces (specifically, the first and second surfaces in the width direction (±x direction) and the second surface in the length direction (±y direction)) are composed of the anodic aluminum oxide film AL as the second patternable material PT2 is patterned.

Referring to FIGS. 7B and 7C, in a state where an upper surface of the first end of the lower metal layer LM in the length direction (±y direction) is covered by the unpatterned portion of the second patternable material PT2, a metal plating process is performed on the second opening OP2.

Specifically, referring to FIG. 7C, the metal plating process is performed on the second opening OP2 to form an upper metal layer UM. The upper metal layer UM is preferably stacked in at least three layers.

The upper metal layer UM is composed of a first metal layer M1 or a second metal layer M2. The upper metal layer UM is stacked in at least three layers, and is provided by alternately stacking the first metal layer M1 and the second metal layer M2. In the drawings, four upper metal layers UM are provided in the second opening OP2, and the second metal layer M2, the first metal layer M1, the second metal layer M2, and the first metal layer M1 are stacked sequentially.

The upper metal layer UM is provided in plural so as to have a dimension greater than that of the lower metal layer LM in the thickness direction (±z direction). As a result of stacking the upper metal layer UM in plural, the above-described first body region BF1 is formed.

The upper metal layer UM is stacked in a state where the unpatterned portion of the second patternable material PT2 is provided on the first end of the lower metal layer LM in the length direction (±y direction). Therefore, the dimension of the upper metal layer UM in the length direction (±y direction) is smaller than that of the lower metal layer (LM) in the length direction (±y direction). The lower metal layer LM has a portion that protrudes in the length direction (±y direction) beyond the upper metal layer UM due to the unpatterned portion of the second patternable material PT2 provided on the first end thereof in the length direction (±y direction). The portion of the lower metal layer LM that protrudes in the length direction (±y direction) beyond the upper metal layer UM corresponds to the protrusion 203 of the second body region BF2 described above.

The upper metal layer UM has a smaller dimension in the length direction (±y direction) than the lower metal layer LM due to the second patternable material PT2, and is stacked in plural to have a greater dimension in the thickness (±z direction) than the lower metal layer LM.

As illustrated in FIG. 7C, after forming the upper metal layer UM in the second opening OP2, the lower metal layer LM, the unpatterned portion of the second patternable material PT2 provided on the first end of the lower metal layer LM in the length direction (±y direction), and the plurality of upper metal layers UM provided at a position where the second patternable material PT2 is patterned are provided in the first opening OP1 of the mold MD.

Here, the second patternable material PT2 is provided in a form that covers an upper surface of the lower metal layer LM in the thickness direction (±z direction) and a side surface of the plurality of upper metal layers UM in the length direction (±y direction). The upper surface of the lower metal layer LM in the thickness direction (±z direction) corresponds to the upper surface of the above-described protrusion 203 in the thickness direction (±z direction), and the side surface of the plurality of upper metal layers UM in the length direction (±y direction) corresponds to the step side surface SP corresponding to the side surface of the above-described first body region BF1 in the length direction (±y direction).

Then, referring to FIG. 7D, the anodic aluminum oxide film AL and the unpatterned portion of the second patternable material PT2 are all removed to obtain metal products MA1 and MA2 composed of the lower metal layer LM and the plurality of upper metal layers UM.

Each of the metal products MA1 and MA2 is provided with a plurality of fine trenches 88 on side surfaces (side surfaces on the x-y plane in the drawings) excluding the upper surface of the lower metal layer LM in the thickness direction (±z direction) covered by the unpatterned portion of the second patternable material PT2, on the side surfaces of the plurality of upper metal layers UM in the length direction (±y direction), on the lower surface of the lower metal layer LM in the thickness direction (±z direction) in contact with the seed layer SD, and on the upper surface of the uppermost metal layer UM in the thickness direction (±z direction) exposed to the outside.

More specifically, in a state before the metal products MA1 and MA2 are obtained, the side surfaces connecting the upper and lower surfaces of the lower metal layer LM in the thickness direction (±z direction) are in contact with the side walls SW1 of the first opening OP1. Since the side walls SW1 of the first opening OP1 are composed of the anodic aluminum oxide film AL, the fine trenches 88 are provided on the side walls SW1. Therefore, the fine trenches 88 formed due to the anodic aluminum oxide film AL are provided on the side surfaces of the lower metal layer LM in contact with the side walls SW1 of the first opening OP1.

In addition, in a state before the metal products MA1 and MA2 are obtained, among the side surfaces connecting the upper and lower surfaces of the plurality of upper metal layers UM in the thickness direction (±z direction), one surface in the length direction (±y direction) is in contact with a side wall SW2 of the second opening OP2 composed of the second patternable material PT2, and the remaining surfaces excluding the one surface composed of the second patternable material PT2 are in contact with side walls SW2 of the second opening OP2 composed of the anodic aluminum oxide film AL.

The one surface of the upper metal layers UM in contact with the side wall SW2 of the second opening OP2 composed of the second patternable material PT2 corresponds to the above-described step side surface SP, and the remaining surfaces of the upper metal layers UM in contact with the side walls SW2 of the second opening OP2 composed of the anodic aluminum oxide film AL correspond to the side surfaces connecting the first surfaces S1 and S1′ and the second surfaces S2 and S2′ of the metal products MA1 and MA2.

Therefore, a first surface of the plurality of upper metal layers UM in the length direction (±y direction) in contact with the side wall SW2 of the second opening OP2 composed of the second patternable material PT2 is not provided with the fine trenches 88, and except for the first surface in the length direction (±y direction) in contact with the side wall SW2 of the second opening OP2 composed of the second patternable material PT2, the side surfaces including a second surface in the length direction (±y direction) and a first surface and a second surface in the width direction (±x direction) are provided with the fine trenches 88.

According to the method of manufacturing the metal products MA1 and MA2, the first opening OP1 is formed first in the mold MD made of the anodic aluminum oxide film AL to form the lower metal layer LM. In a state where the lower metal layer LM is provided, the second patternable material PT2 is provided and partially patterned to form the second opening OP2. With this, according to the method of manufacturing the metal products MA1 and MA2, one of side walls of the mold MD forming the side surfaces connecting the upper and lower surfaces of the metal products MA1 and MA2 in the thickness direction (±z direction) is not provided with the fine trenches 88, and the remaining side walls of the mold MID excluding the one side wall not provided with the fine trenches 88 are provided with the fine trenches 88. Therefore, the metal products MA1 and MA2 manufactured according to the method of manufacturing the metal products MA1 and MA2 have a structure in which the first and second body regions BF1 and BF2 having different dimensions in the length direction (±y direction) and thickness direction (±z direction) are provided, and the fine trenches 88 are provided only on the remaining side surfaces excluding the step side surface SP formed due to the difference in thickness between the first and second body regions BF1 and BF2.

When only a photoresist is used in the manufacture of the metal products MA1 and MA2, it is difficult to sufficiently increase the height of the mold MD with the use of a single-layer photoresist. Therefore, the thickness of the metal products MA1 and MA2 cannot also be sufficiently increased. The metal products MA1 and MA2 need to be manufactured with a predetermined thickness in consideration of electrical conductivity, restoring force, brittle fracture, etc. In order to increase the thickness of the metal products MA1 and MA2, a mold in which photoresists are stacked in multiple layers may be used. However, in this case, each photoresist layer is slightly stepped, so that a problem occurs in that side surfaces of the metal products MA1 and MA2 are not formed vertically and a stepped area minutely remains. In addition, when the photoresists are stacked in multiple layers, it is difficult to accurately reproduce the shape of the metal products MA1 and MA2 having a dimension range of equal to or less than several tens of μm.

However, as in the method of manufacturing the metal products MA1 and MA2 according to the present disclosure, when manufacturing the metal products MA1 and MA2 using the mold MD made of the anodic aluminum oxide film AL, metal products MA1 and MA2 having vertical side surfaces can be produced.

Meanwhile, when only the anodic aluminum oxide film AL is used as the mold MD, it may be difficult to implement a three-dimensional shape (e.g., the metal products MA1 and MA2 having the protrusion 203) in the height direction.

However, according to the method of manufacturing the products MA1 and MA2 according to the present disclosure, by using a plating mold MD provided with a composite of the anodic aluminum oxide film AL and the second patternable material PT2, metal products MA1 and MA2 having a three-dimensional shape in the height direction can be manufactured.

Hereinafter, a test device 1000 according to a preferred embodiment of the present disclosure will be described.

FIG. 8 is view illustrating, as an example, a test device 1000 having the metal product MA1 according to the first embodiment. The test device 1000 may be provided with the metal product MA2 according to the second embodiment.

The test device 1000 may be a test device 1000 used in a semiconductor manufacturing process, and may be, for example, a probe card or a test socket. When the test device 1000 is a probe card for testing a semiconductor chip or a test socket for testing a semiconductor package, the metal product MA1 according to the first embodiment may be an electrically conductive contact pin.

However, the test device 1000 that can use the metal products MA1 and MA2 is not limited thereto and includes any device for checking whether a test object 1001 is defective by applying electricity.

The test object 1001 of the test device 1000 may include a semiconductor device, a memory chip, a microprocessor chip, a logic chip, a light-emitting device, or a combination thereof. For example, the test object 1001 includes a logic LSI (such as an ASIC, an FPGA, and an ASSP), a microprocessor (such as a CPU and a GPU), a memory (such as a DRAM and a hybrid memory cube (HMC), a magnetic RAM (MRAM), a phase-change memory (PCM), a resistive RAM (ReRAM), a ferroelectric RAM (FeRAM), a flash memory (such as NAND flash), a semiconductor light-emitting device (such as an LED, a mini LED, and a micro-LED), a power device, an analog IC (such as a DC-AC converter and an insulating gate bipolar transistor (IGBT)), an MEMS (such as an acceleration sensor, a pressure sensor, a vibrator, and a gyro sensor), a wireless device (such as a GPS, an FM, an NFC, an RFEM, an MMIC, and a WLAN), a discrete device, a BSI, a CIS, a camera module, a CMOS, a passive device, a GAW filter, an RF filter, an RF IPD, an APE, and a BB.

The test device 1000 includes a guide plate GP (including an upper guide plate GP1 and a lower guide plate GP2) into which the metal product MA1 according to the first embodiment is inserted and installed, and a circuit wiring portion 1002 electrically connected to a side of the metal product MA1 in the length direction (±y direction) through a pad CP. The metal product MA1 includes an elastic portion 300 so that a first connection portion 100 is elastically displaced relative to a second connection portion 200 in the length direction (±y direction), and the second connection portion 200 is connected to the test object 1001.

The guide plate GP includes the upper guide plate GP1 and the lower guide plate GP2 spaced apart from each other, and the metal product MA1 is installed through a through hole of each of the upper guide plate GP1 and the lower guide plate GP2. Here, the metal product MA1 is fixed to the upper guide plate GP1 by a locking portion 407 provided on an outer wall portion 400 of the metal product MA1.

Although the exemplary embodiments of the present disclosure have been described for illustrative purposes, those skilled in the art will appreciate that various modifications, additions, and substitutions are possible, without departing from the scope and spirit of the present disclosure as disclosed in the accompanying claims.

What is claimed is:

1. A metal product comprising:
an overall length in a length direction;
an overall thickness in a thickness direction orthogonal to the length direction;
an overall width in a width direction orthogonal to the length direction,
wherein the metal product is divided into a first body region and a second body region in the thickness direction,
a step side surface is formed due to a dimensional difference in the thickness direction between the first body region and the second body region,
the first body region comprises first side surfaces, the first body region is provided on the first side surfaces excluding the step side surface with a plurality of first fine trenches formed in a form of grooves extending along the thickness direction and arranged in parallel along the first side surfaces, and
the second body region comprises second side surfaces, the second body region is provided on the second side surfaces with a plurality of second fine trenches formed in the form of grooves extending along the thickness direction and arranged in parallel along the second side surfaces.

2. The metal product of claim 1, wherein the metal product includes a first surface and a second surface opposite to the first surface,
wherein the first side surfaces and the second side surfaces connect the first surface and the second surface to each other, and the first fine trenches and the second fine trenches are not formed on the first surface and the second surface.

3. The metal product of claim 1, wherein the first fine trenches and the second fine trenches have a depth in a range of 20 nm to 1 μm.

4. The metal product of claim 1, wherein a portion of the second body region forms a protrusion that protrudes beyond the first body region,
wherein the second body region excluding the protrusion has a shape that corresponds to a shape of the first body region.

5. The metal product of claim 1, wherein the first body region has a thickness greater than a thickness of the second body region.

6. The metal product of claim 1, wherein the metal product is an electrically conductive contact pin that is connected to a test object and tests electrical characteristics of the test object.

7. A test device, comprising:
a metal product;
a guide plate into which the metal product is inserted and installed; and
a circuit wiring portion configured to be electrically connected to a side of the metal product,
wherein the metal product comprises:
a first body region; and
a second body region having a dimension smaller than a dimension of the first body region in a thickness direction,
wherein a step side surface is formed due to a dimensional difference in the thickness direction between the first region and the second body region,
the first body region comprises first side surfaces, the first body region is provided on the first side surfaces excluding the step side surface with a plurality of first fine trenches formed in a form of grooves extending along the thickness direction and arranged in parallel along the first side surfaces, and
the second body region comprises second side surfaces, the second body region is provided on the second side surfaces with a plurality of second fine trenches formed in the form of grooves extending along the thickness direction and arranged in parallel along the second side surfaces.

8. A method of manufacturing metal product, comprising:
forming a first opening by etching a portion of an anodic aluminum oxide film in a thickness direction;
forming a lower metal layer by subjecting the first opening to a plating process;
forming a patternable material on the lower metal layer;
patterning at least a portion of the patternable material to form a second opening;
forming an upper metal layer by subjecting the second opening to the plating process; and
removing the anodic aluminum oxide film and the patternable material.

9. The method of claim 8, wherein in the forming of the lower metal layer,
the lower metal layer is formed to have a dimension smaller than a dimension of the first opening in the thickness direction.

10. The method of claim 8, wherein in the forming of the upper metal layer,
the upper metal layer is formed to have a dimension greater than a dimension of the lower metal layer in the thickness direction.

11. The method of claim 8, wherein after the forming of the upper metal layer,
the patternable material covers an upper surface of the lower metal layer in the thickness direction and a side surface of the upper metal layer in a length direction.
